(19) United States
(12) Patent Application Publication
(10) Pub. No.: US 2016/0246111 A1
(43) Pub. Date: Aug. 25, 2016

(54) DISPLAY PANEL AND METHOD OF FABRICATING THE SAME

(71) Applicant: AU Optronics Corp., Hsin-Chu (TW)

(72) Inventors: Yao-Ming Chen, Hsin-Chu (TW); Po-Yuan Shen, Hsin-Chu (TW); Chia-Fang Chen, Hsin-Chu (TW)

(21) Appl. No.: 15/009,792

(22) Filed: Jan. 28, 2016

(30) Foreign Application Priority Data
Feb. 25, 2015 (TW) 104106092

(51) Int. Cl. G02F 1/1335; H01L 27/12; G02F 1/1343; H04N 9/12; G02F 1/1368

(52) U.S. Cl. CPC G02F 1/133516; H04N 9/12; G02F 1/1368; G02F 1/134309; G02F 1/133512; H01L 27/1214; H01L 27/1262; G02F 2001/136222

(57) ABSTRACT

A display panel and a fabrication method thereof are provided. The display panel includes a substrate, a plurality of thin film transistor devices, color filters having different colors and a plurality of auxiliary color filter patterns. The thin film transistor devices and the color filters are disposed in corresponding pixel regions of the substrate, and each color filter layer has an opening uncovering one corresponding thin film transistor device. The auxiliary color filter patterns are respectively disposed in the openings of the color filter layers, and the auxiliary color filter patterns have the same light transmission spectrum.

### BACKGROUND OF THE INVENTION

1. Field of the Invention

The present invention relates to a display panel and method of fabricating the same, and more particularly, to a display panel with high aperture ratio and low color deviation and method of fabricating the same.

2. Description of the Prior Art

Display panel e.g. liquid crystal display (LCD) panel is normally assembled by an array substrate and a color filter substrate (CF substrate). The array substrate includes thin film transistor (TFT) devices and peripheral circuit disposed thereon, and the CF substrate includes color filters e.g. red color filters, green color filters and blue color filters formed thereon. Considering the orientation shift between the array substrate and the CF substrate in assembly process, the width of black matrix must be enlarged to shield light leakage. The width incremental of the black matrix, however, reduces the area of light transmission region of the display panel, and thus adversely affects the aperture ratio of the display panel.

### SUMMARY OF THE INVENTION

It is therefore one of the objectives of the present disclosure to provide a display panel and a fabrication method thereof to increase aperture ratio and to diminish color deviation.

According to an embodiment of the present disclosure, a display panel is provided. The display panel includes a first substrate, a plurality of thin film transistor (TFT) devices, a first color filter, a second color filter and a plurality of auxiliary color filter patterns. The first substrate has a first sub-pixel region and a second sub-pixel region. The thin film transistor (TFT) devices are disposed on a surface of the first substrate and located respectively in the first sub-pixel region and the second sub-pixel region. The first color filter is disposed on the surface of the first substrate of the first sub-pixel region, wherein the first color filter has a first opening at least partially corresponding to the thin film transistor device in the first sub-pixel region. The second color filter is disposed on the surface of the first substrate of the second sub-pixel region, wherein the second color filter has a second opening at least partially corresponding to the thin film transistor device in the second sub-pixel region, and the first color filter and the second color filter have different light transmission spectra. The auxiliary color filter patterns are respectively disposed in the first openings and the second openings, wherein the auxiliary color filter patterns disposed in the first openings and the second openings have the same light transmission spectrum.

According to another embodiment of the present disclosure, a method of fabricating a display panel is provided. The fabrication method includes the following steps. A first substrate is provided. A plurality of thin film transistor (TFT) devices are formed on the first substrate, wherein the thin film transistor devices are respectively disposed in a first sub-pixel region and a second sub-pixel region of the first substrate. A first color filter is formed in the first sub-pixel region of the first substrate, wherein the first color filter has a first opening at least partially corresponding to the thin film transistor device in the first sub-pixel region. A second color filter is formed in the second sub-pixel region of the first substrate, wherein the second color filter has a second opening at least partially corresponding to the thin film transistor device in the second sub-pixel region, and the first color filter and the second color filter have different light transmission spectra. A plurality of auxiliary color filter patterns are formed in the first openings and the second openings, wherein the auxiliary color filter patterns disposed in the first openings and the second openings have the same light transmission spectrum.

The color filters of the display panel of the present disclosure are disposed on the array substrate, and thus the aperture ratio of the display panel is improved. In addition, the TFT devices of the sub-pixel regions configured to display images of different colors are covered with the auxiliary color filter patterns of the same color, and thus all the TFT devices have identical leakage currents and identical device characteristic. Accordingly, color deviation is avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a display panel according to a comparative embodiment of the present disclosure.

FIG. 2 is a diagram illustrating the relation between light absorption coefficient of the semiconductor channel layer and wavelength and the spectrum of back light.

FIG. 3 is a schematic diagram illustrating a display panel according to a first embodiment of the present disclosure.

FIG. 4 is a schematic diagram illustrating a display panel according to an alternative embodiment of the first embodiment of the present disclosure.

FIG. 5 is a schematic diagram illustrating a display panel according to a second embodiment of the present disclosure.

FIG. 6 is a schematic diagram illustrating a display panel according to an alternative embodiment of the second embodiment of the present disclosure.

FIG. 7 is a schematic diagram illustrating a display panel according to a third embodiment of the present disclosure.

FIG. 8 is a flow chart illustrating a method of fabricating a display panel according an embodiment of the present disclosure.

### DETAILED DESCRIPTION

To provide a better understanding of the present invention to the skilled persons in the technology of the present invention, preferred embodiments will be detailed as follows. The preferred embodiments of the present invention are illustrated in the accompanying drawings with numbered elements to elaborate the contents and effects to be achieved.

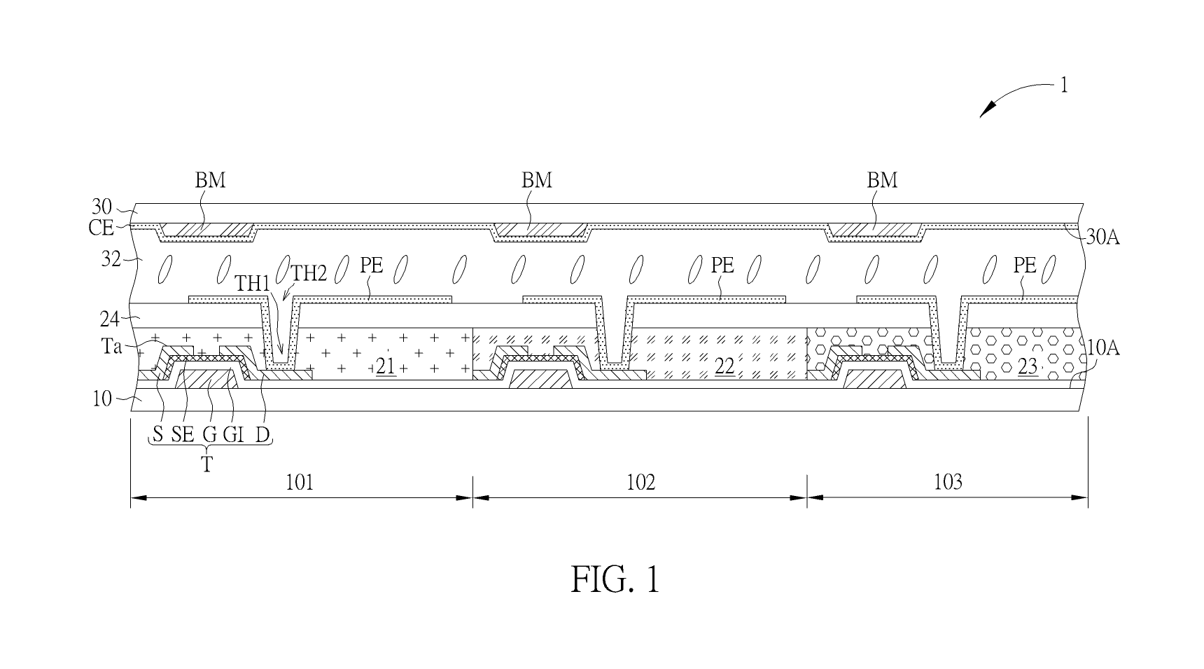

Refer to FIG. 1. FIG. 1 is a schematic diagram illustrating a display panel according to a comparative embodiment of the present disclosure. As shown in FIG. 1, the display panel 1 of the comparative embodiment includes a first substrate 10, a plurality of thin film transistor (TFT) devices T, a first color filter 21, a second color filter 22, a third color filter 23, a plurality of pixel electrodes PE, a second substrate 30, an opto-electric medium layer 32, a black matrix BM and a common electrode CE. The first substrate 10 is an array substrate, which may be a transparent substrate e.g. a glass substrate, a plastic substrate or other suitable rigid or flexible substrates. The first substrate 10 has a first sub-pixel region 101, a second sub-pixel region 102 and a third sub-pixel region 103 for displaying images of three different colors. The TFT devices T are disposed on a surface 10A of the first substrate 10 and respectively located in the first sub-pixel region 101, the second sub-pixel region 102 and the third sub-pixel region 103. The TFT device T includes a gate electrode G, a gate insulating layer GI, a semiconductor channel layer SE, a source electrode S and a drain electrode D. The first color filter 21, the second color filter 22 and the third color filter 23 are disposed on the surface 10A of the first substrate 10 and respectively located in the first sub-pixel region 101, the second sub-pixel region 102 and the third sub-pixel region 103, and the first color filter 21, the second color filter 22 and the third color filter 23 respectively cover the corresponding TFT devices T. In addition, each of the first color filter 21, the second color filter 22 and the third color filter 23 has a first contact hole TH1, and the first contact holes TH1 respectively expose or uncover the drain electrodes D of the TFT devices T. In the comparative embodiment, the first color filter 21, the second color filter 22 and the third color filter 23 are a red color filter, a green color filter and a blue color filter respectively, i.e. the first sub-pixel region 101, the second sub-pixel region 102 and the third sub-pixel region 103 are respectively a red sub-pixel region, a green sub-pixel region and a blue sub-pixel region, which together form a pixel region able to provide full-color images. Also, an overcoat layer 24 may selectively covers the first color filter 21, the second color filter 22 and the third color filter 23, and the overcoat layer 24 includes a plurality of second contact holes TH2 connecting the first contact holes TH1 respectively. The pixel electrodes PE are disposed on the surface 10A of the first substrate 10 and respectively located in the first sub-pixel region 101, the second sub-pixel region 102 and the third sub-pixel region 103, and the pixel electrodes PE are electrically connected to the drain electrodes D of the TFT devices T respectively through the first contact holes TH1 and the second contact holes TH2. The second substrate 30 is a counter substrate, which is disposed opposite to the first substrate 10, and the second substrate 30 may be a transparent substrate e.g. a glass substrate, a plastic substrate or other suitable rigid or flexible substrates. The black matrix BM (also referred to as a light-shielding pattern) is disposed on a surface 30A of the second substrate 30. The common electrode CE is disposed on the surface 30A of the second substrate 30 and the black matrix BM. In the comparative embodiment, the opto-electrical medium layer 32 may include, for instance, a liquid crystal layer interposed between the surface 10A of the first substrate 10 and the surface 30A of the second substrate 30.

As shown in FIG. 1, the display panel 1 of the comparative embodiment is a COA (color filter on array) display panel, in which the first color filter 21, the second color filter 22 and the third color filter 23 are disposed on the first substrate (array substrate) 10, instead of on the second substrate (counter substrate) 30, therefore, light leakage due to the alignment shift between the first substrate 10 and the second substrate 30 is avoided. Consequently, the width of the black matrix BM can be reduced to increase the aperture ratio.

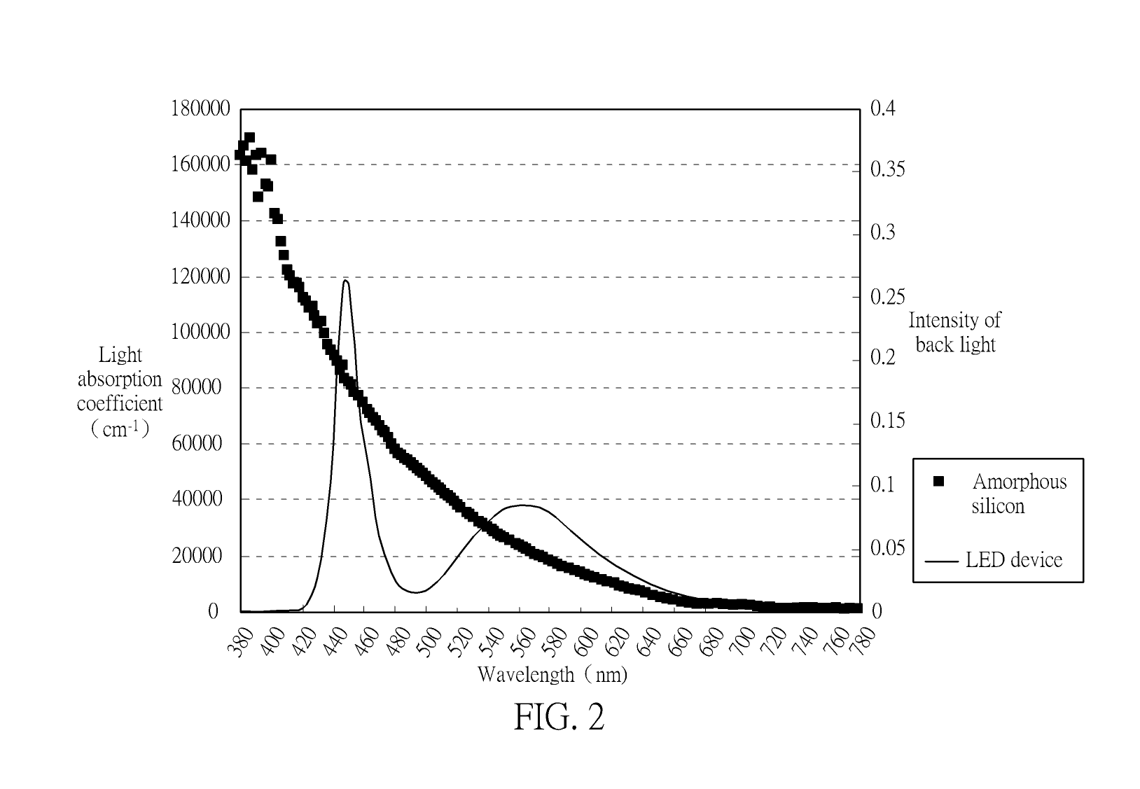

The black matrix BM is able to shield most part of environmental light, but some environmental light may still enter the display panel 1, penetrates through the first color filter 21, the second color filter 22 and the third color filter 23, and reaches the semiconductor channel layers SE of the TFT devices T. Furthermore, the semiconductor channel layers SE of the TFT devices T may also be irradiated by back light provided by backlight module (not shown) due to reflection or refraction effect. When the semiconductor channel layer SE is irradiated by environmental light and/or back light, current leakage will occur to the TFT device T. As a result, the device characteristic will be affected, for example, threshold voltage will be shifted and lifetime will be reduced. Refer to FIG. 2, as well as FIG. 1. FIG. 2 is a diagram illustrating the relation between light absorption coefficient of the semiconductor channel layer and wavelength and the spectrum of back light, wherein amorphous silicon is exemplarily selected as the material of the semiconductor channel layer SE, and white light provided by white light LED device is exemplarily selected as the back light. As shown in FIG. 2, the light absorption coefficient of amorphous silicon is significantly inversely proportional to wavelength, that is, amorphous silicon has higher light absorption coefficient with respect to light beam with short wavelength e.g. blue light, and amorphous silicon has lower light absorption coefficient with respect to light beam with long wavelength e.g. red light, wherein the red light wavelength (λ_{R}) is longer than the blue light wavelength (λ_{B}). In addition, within the spectrum of the back light emitted by white light LED device, the intensity of light within blue light wavelength range is usually higher than the intensity of light within green light and red light wavelength ranges. In other words, the environmental light (white light) or the back light (white light) will be filtered and become red light within red light wavelength (λ_{R}) after penetrating through the first color filter (red color filter) 21, and the TFT device T of the first sub-pixel region 101 will have a first leakage current when the semiconductor channel layer SE thereof is irradiated by the red light. The environmental light (white light) or the back light (white light) will be filtered and become green light within green light wavelength (2 after penetrating through the second color filter (green color filter) 22, and the TFT device T of the second sub-pixel region 102 will have a second leakage current when the semiconductor channel layer SE thereof is irradiated by the green light. The environmental light (white light) or the back light (white light) will be filtered and become blue light within blue light wavelength (λ_{B}) after penetrating through the third color filter (blue color filter) 23, and the TFT device T of the third sub-pixel region 103 will have a third leakage current when the semiconductor channel layer SE thereof is irradiated by the blue light. Since the red light wavelength (λ_{R}) is longer than the green light wavelength (λ_{G}) and the green light wavelength (λ_{G}) is longer than blue light wavelength (λ_{B}), the first leakage current is smaller than the second leakage current, and the second leakage current is smaller than the third leakage current. In conclusion, the semiconductor channel layers SE of the TFT devices T of the sub-pixels of different colors are irradiated by light beams of different wavelengths, and thus the degrees of current leakage in the TFT devices T of the sub-pixels of different colors are diverse. This causes the TFT devices T of the sub-pixels of different colors to exhibit diverse device characteristics, deteriorating display effect. For example, cross-talk phenomenon will be observed when displaying an image having high greyscale difference due to light leakage of the TFT devices T or parasitic capacitance. Since the degrees of leakage current of the TFT devices T of the sub-pixels of different colors are diverse, that is, the leakage current in red sub-pixel is smaller than the leakage current in green sub-pixel and the leakage current in blue sub-pixel, a reddish image will be observed when observing the display panel 1. Thus, there is a space for the display panel 1 of the comparative embodiment to be improved.

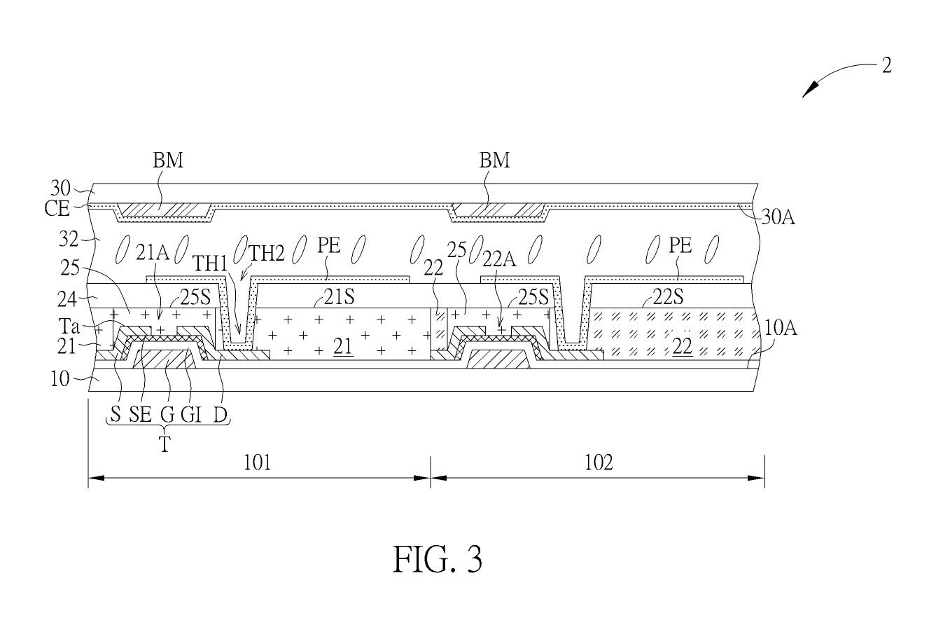

Refer to FIG. 3. FIG. 3 is a schematic diagram illustrating a display panel according to a first embodiment of the present disclosure. As shown in FIG. 3, the display panel 2 of this embodiment is an LCD panel, in which a first substrate 10 may only include two types of sub-pixel regions configured to display images of two different colors. In this embodiment, the sub-pixel regions are first sub-pixel regions 101 and second sub-pixel regions 102. The display panel 2 includes a plurality of TFT devices T, a first color filter 21, a second color filter 22, a plurality of auxiliary color filter patterns 25, a plurality of pixel electrodes PE, a second substrate 30, an opto-electric medium layer 32, a black matrix BM and a common electrode CE. The TFT devices T are disposed on a surface 10A of the first substrate 10 and respectively located in the first sub-pixel region 101 and the second sub-pixel region 102. The TFT device T includes a gate electrode G, a gate insulating layer GI, a semiconductor channel layer SE, a source electrode S and a drain electrode D. The gate electrode G is electrically connected to a corresponding gate line (not shown), and the source electrode S is electrically connected to a corresponding data line (not shown). The material of the gate electrode G, the source electrode S and the drain electrode D may be e.g. metal or alloy, but not limited thereto. The material of the gate insulating layer GI may be inorganic insulating material and/or organic insulating material, but not limited thereto; the material of the semiconductor channel layer SE may be silicon e.g. amorphous silicon or polycrystalline silicon, or oxide semiconductor material e.g. indium gallium zinc oxide (IGZO), but not limited thereto. The TFT device T of this embodiment is a bottom gate type TFT device, but not limited thereto. For example, the TFT device T may be a top gate type TFT or other types of TFT devices.

The first color filter 21 is disposed on the surface 10A of the first substrate 10 and located in the first sub-pixel region 101, wherein the first color filter 21 has a first opening 21A at least partially corresponding to the TFT device T of the first sub-pixel region 101. The second color filter 22 is disposed on the surface 10A of the first substrate 10 and located in the second sub-pixel region 102, wherein the second color filter 22 has a second opening 22A at least partially corresponding to the TFT device T of the second sub-pixel region 102. In this embodiment, the first opening 21A and the second opening 22A may partially uncover the top surfaces Ta of the TFT devices T respectively. In an alternative embodiment, other layers e.g. a dielectric layer or a passivation layer may cover the TFT devices T, in such a case, the first opening 21A and the second opening 22A may partially uncover the top surface of the dielectric layer or the passivation layer over the top surfaces Ta of the TFT devices T. In addition, the first color filter 21 and the second color filter 22 have different light transmission spectra, i.e. when white light passes through the first color filter 21 and the second color filter 22, the color and wavelength range of light coming out of the first color filter 21 are different from the color and wavelength range of light coming out of the second color filter 22. For example, the first color filter 21 is a yellow color filter and the second color filter 22 is a blue color filter, but not limited thereto. By virtue of the aforementioned arrangement, the first sub-pixel region 101 is a yellow sub-pixel region and the second sub-pixel region 102 is a blue sub-pixel region, which together form a pixel region for providing full-color images. In an alternative embodiment, the first color filter 21 and the second color filter 22 are selected from the group consisting of a red color filter, a green color filter, a blue color filter, a yellow color filter, a cyan color filter, a magenta color filter and a color filter of another different color. The auxiliary color filter patterns 25 are disposed in the first openings 21A and the second openings 22A respectively, and the auxiliary color filter pattern 25 is a single-layered color filter pattern or a color filter layer of one single color, further the auxiliary color filter pattern 25 is not stacked by a plurality of color filter layers of different colors. The auxiliary color filter patterns 25 disposed in the first openings 21A and the second openings 22A have the same light transmission spectrum. In other words, after passing through the auxiliary color filter patterns 25 disposed in the first openings 21A and the second openings 22A, white light will become color light of the same color. For example, the auxiliary color filter pattern 25 is selected from the group consisting of a red color filter, a green color filter, a blue color filter, a yellow color filter, a cyan color filter a magenta color filter and a color filter of another different color.

In this embodiment, the first color filter 21 or the second color filter 22 has the same light transmission spectrum as the auxiliary color filter patterns 25, and the light transmission spectrum of the auxiliary color filter pattern 25 is preferably equal to the first color filter 21 or the second color filter 22 which has the higher light transmission spectrum. Consequently, the leakage currents of all of the TFT devices T are weaker and consistent with each other, and the device characteristic of all the TFT devices T is uniform. In an embodiment, the light transmission spectrum of the first color filter 21 is higher than the light transmission spectrum of the second color filter 22, e.g. the first color filter 21 is a yellow color filter, the second color filter 22 is a blue color filter, and the auxiliary color filter pattern 25 is either a yellow color filter or a blue color filter. The material of the first color filter 21, the second color filter 22 and the auxiliary color filter pattern 25 may be photosensitive material such as color photoresist, which can be formed by exposure-and-development process. For example, the auxiliary color filter pattern 25 and either one of the first color filter 21 and the second color filter 22 (e.g. the first color filter 21) maybe formed by the same exposure-and-development process, while the other one of the first color filter 21 and the second color filter (e.g. the second color filter 22) may be formed by another exposure-and-development process, but not limited thereto. The material of the first color filter 21, the second color filter 22 and the auxiliary color filter pattern 25 may include ink or other suitable material, and may be formed by inkjet printing, coating or other processes.

In addition, there are no other color filters disposed inside the first opening 21A and the second opening 22A, except for the auxiliary color filter pattern 25. In other words, the auxiliary color filter pattern 25 may have single-layered structure, which has the advantages of simplified process, low cost, better yield and easy to control. The first opening 21A and the second opening 22A may be filled up with the auxiliary color filter patterns 25, but not limited thereto. In this embodiment, the top surfaces 25S of the auxiliary color filter patterns 25 disposed in the first openings 21A and the second openings 22A, the first top surface 21S of the first color filter 21 and the second top surface 22S of the second color filter 22 are substantially coplanar, but not limited thereto. Also, the auxiliary color filter pattern 25 may be in physical contact with the top surface Ta of the TFT device T, but not limited thereto. In an alternative embodiment, an insulating layer or other layers may be optionally disposed between the auxiliary color filter pattern 25 and the TFT device T. Furthermore, in this embodiment, the auxiliary color filter pattern 25 at least fully covers the semiconductor channel layer SE of the TFT device T, i.e. the area of the auxiliary color filter pattern 25 is larger than that of the semiconductor channel layer SE, and the auxiliary color filter pattern 25 and the semiconductor channel layer SE overlap in the vertical projection direction.

The first color filter 21 and the second color filter 22 each further has a first contact hole TH1 at least partially uncovering the corresponding drain electrode D. The overcoat layer 24 is disposed on the surface 10A of the first substrate 10 covering the first color filter 21, the second color filter 22 and the auxiliary color filter patterns 25, wherein the overcoat layer 24 has a plurality of second contact holes TH2 connecting the first contact holes TH1 respectively. The pixel electrodes PE are disposed on the overcoat layer 24 and disposed in the first sub-pixel region 101 and the second sub-pixel region 102 respectively, and each of the pixel electrodes PE is electrically connected to the corresponding drain electrode D through the corresponding first contact hole TH1 and the corresponding second contact hole TH2. The opto-electric medium layer 32 may include, for example, a liquid crystal layer disposed between the surface 10A of the first substrate 10 and the surface 30A of the second substrate 30. The pixel electrode PE and the common electrode CE are able to drive the opto-electric medium layer 32 so that back light is able to pass through the opto-electric medium layer 32 and move toward the second substrate 30 to display images.

Since the first color filter 21 and the second color filter 22 are disposed on the first substrate (array substrate) 10 instead of on the second substrate (counter substrate) 30, the display panel 2 of this embodiment has the advantage of high aperture ratio. In addition, the TFT device T of each sub-pixel region is covered with the auxiliary color filter pattern 25 of the same color (the same light transmission spectrum), and thus the environmental light (white light) or the back light (white light) after passing through the auxiliary color filter patterns 25 will become light of the same wavelength. In such a case, when the TFT devices T of the first sub-pixel region 101 and the second sub-pixel region 102 are irradiated by the light of the same wavelength, the leakage currents are identical. Consequently, each of the TFT devices has identical device characteristic, and color deviation is avoided.

The display panel and method of fabricating the same are not limited by the aforementioned embodiment, and may have other different preferred embodiments. To simplify the description, the identical components in each of the following embodiments are marked with identical symbols. For making it easier to compare the difference between the embodiments, the following description will detail the dissimilarities among different embodiments and the identical features will not be redundantly described.

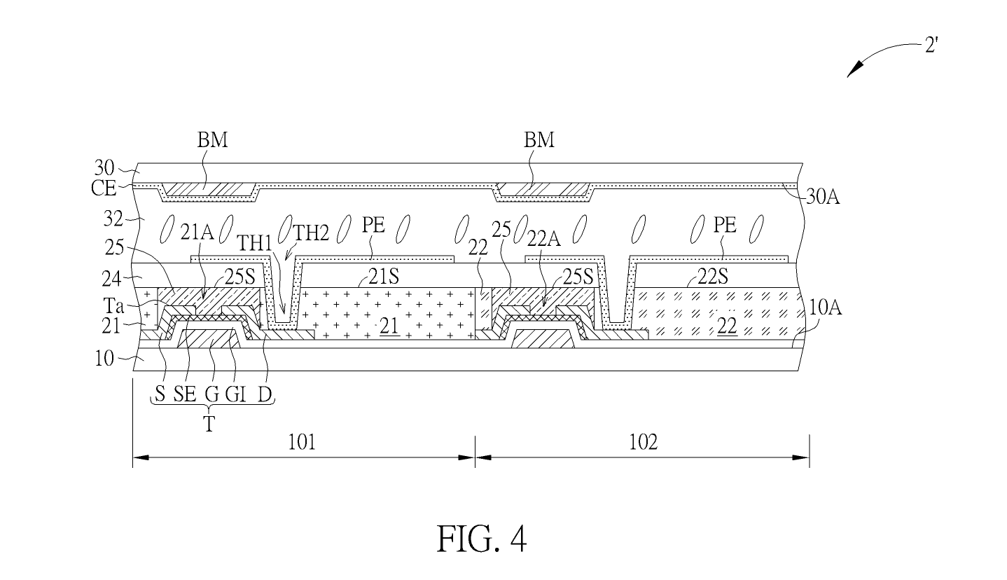

Refer to FIG. 4. FIG. 4 is a schematic diagram illustrating a display panel according to an alternative embodiment of the first embodiment of the present disclosure. As shown in FIG. 4, in the display panel 2′ of the alternative embodiment, the light transmission spectrum of the auxiliary color filter patterns 25 is different from the light transmission spectrum of the first color filter 21 and the light transmission spectrum of the second color filter 22. For example, the light transmission wavelength of the auxiliary color filter patterns 25 is longer than the light transmission wavelength of the first color filter 21 and the light transmission wavelength of the second color filter 22. Accordingly, the leakage currents and device characteristics of the TFT devices T are identical, and color deviation is avoided. For example, the first color filter 21 is a yellow color filter, the second color filter 22 is a blue color filter, and the auxiliary color filter pattern 25 may be a red color filter, but not limited thereto.

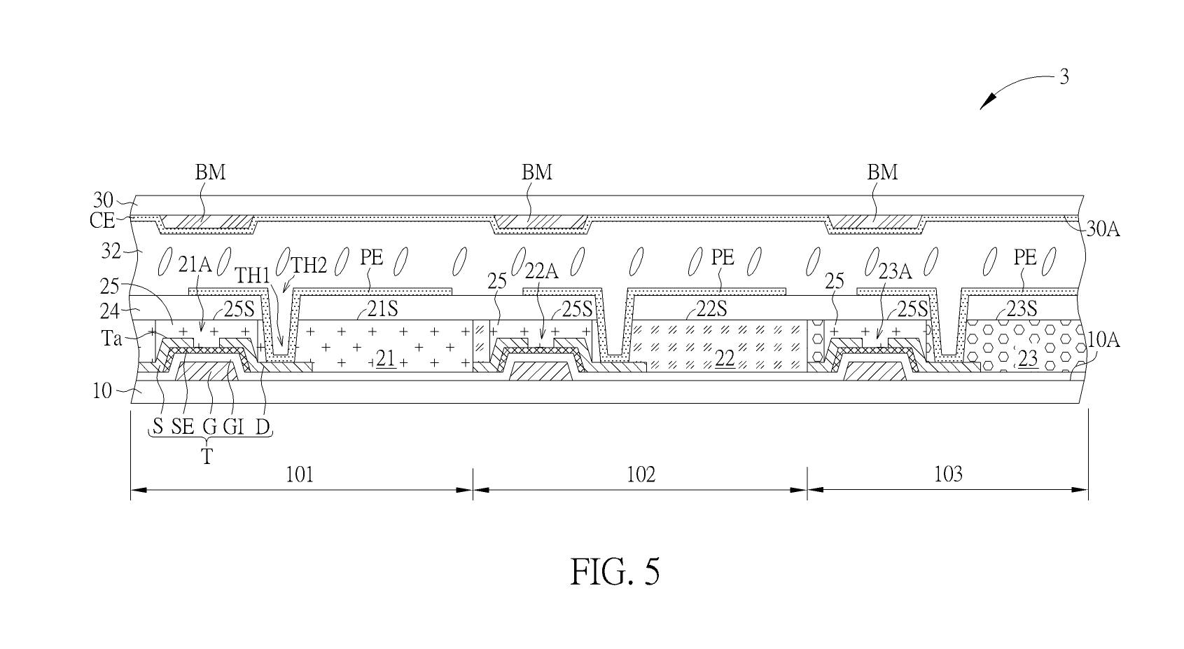

Refer to FIG. 5. FIG. 5 is a schematic diagram illustrating a display panel according to a second embodiment of the present disclosure. As shown in FIG. 5, different from the first embodiment, the display panel 3 of this embodiment includes three or more sub-pixel regions configured to display three or more images of different colors, e.g. a first sub-pixel region 101, a second sub-pixel region 102 and a third sub-pixel region 103. The display panel 3 further includes a first color filter 21, a second color filter 22, a third color filter 23 and a plurality of auxiliary color filter patterns 25. The first color filter 21 is disposed on the surface 10A of the first substrate 10 and located in the first sub-pixel region 101, wherein the first color filter 21 has a first opening 21A at least partially corresponding to the TFT device T of the first sub-pixel region 101. The second color filter 22 is disposed on the surface 10A of the first substrate 10 and located in the second sub-pixel region 102, wherein the second color filter 22 has a second opening 22A at least partially corresponding to the TFT device T of the second sub-pixel region 102. The third color filter 23 is disposed on the surface 10A of the first substrate 10 and located in the third sub-pixel region 103, wherein the third color filter 23 has a third opening 23A at least partially corresponding to the TFT device T of the third sub-pixel region 103. In this embodiment, the first opening 21A, the second opening 22A and the third opening 23A may partially uncover the top surfaces Ta of the TFT devices T respectively. In an alternative embodiment, other layers e.g. a dielectric layer or a passivation layer may cover the TFT devices T, in such a case, the first opening 21A, the second opening 22A and the third opening 23A may partially uncover the top surface of the dielectric layer or the passivation layer over the top surfaces Ta of the TFT devices T. In addition, the first color filter 21, the second color filter 22 and the third color filter 23 have different light transmission spectra, for example, the first color filter 21 is a red color filter, the second color filter 22 is a green color filter and the third color filter 23 is a blue color filter, but not limited thereto. By virtue of the aforementioned arrangement, the first sub-pixel region 101, the second sub-pixel region 102 and the third sub-pixel region 103 are respectively a red sub-pixel region, a green sub-pixel region and a blue sub-pixel region, which together forma pixel region for providing full-color images. In an alternative embodiment, the first color filter 21, the second color filter 22 and the third color filter 23 are selected from the group consisting of a red color filter, a green color filter, a blue color filter, a yellow color filter, a cyan color filter, a magenta color filter and a color filter of another different color. The auxiliary color filter patterns 25 are disposed in the first openings 21A, the second openings 22A and the third opening 23A respectively. In this embodiment, the first opening 21A, the second opening 22A and the third opening 23A may be filled up with the auxiliary color filter patterns 25, and the top surfaces 25S of the auxiliary color filter patterns 25 disposed in the first openings 21A, the second openings 22A and the third openings 23A, the first top surface 21S of the first color filter 21, the second top surface 22S of the second color filter 22 and the third top surface 23S of the third color filter 23 are substantially coplanar, but not limited thereto. In addition, the auxiliary color filter patterns 25 disposed in the first openings 21A, the second openings 22A and the third openings 23A have the same light transmission spectrum. For example, the auxiliary color filter pattern 25 is selected from the group consisting of a red color filter, a green color filter, a blue color filter, a yellow color filter, a cyan color filter a magenta color filter and a color filter of another different color. In this embodiment, one of the first color filter 21, the second color filter 22 or the third color filter 23 has the same light transmission spectrum as the auxiliary color filter patterns 25, and the light transmission spectrum of the auxiliary color filter pattern 25 is preferably equal to the first color filter 21, the second color filter 22 or the third color filter 23 which has the higher light transmission spectrum. Consequently, the leakage currents of all of the TFT devices T are weaker and consistent, and the device characteristic of all the TFT devices T is uniform. For example, the first color filter 21 is a red color filter, the second color filter 22 is a green color filter, the third color filter 23 is a blue color filter, and the auxiliary color filter pattern 25 may be a red color filter, a green color filter or a blue color filter. Preferably, the auxiliary color filter pattern 25 is a red color filter, and may be formed by the same process as one of the first color filter 21, the second color filter 22 or the third color filter 23, but not limited thereto. Furthermore, in this embodiment, the auxiliary color filter pattern 25 at least fully covers the semiconductor channel layer SE of the TFT device T, i.e. the area of the auxiliary color filter pattern 25 is larger than that of the semiconductor channel layer SE, and the auxiliary color filter pattern 25 and the semiconductor channel layer SE overlap in the vertical projection direction.

Similar to the first embodiment, the first color filter 21, the second color filter 22 and the third color filter 23 are disposed on the first substrate (array substrate) 10 instead of on the second substrate (counter substrate) 30, and thus the display panel 3 of this embodiment has the advantage of high aperture ratio. In addition, the TFT device T of each sub-pixel region is covered with the auxiliary color filter pattern 25 of the same color (the same light transmission spectrum), and thus the environmental light (white light) or the back light (white light) after passing through the auxiliary color filter patterns 25 will become light of the same wavelength. In such a case, when the TFT devices T of the first sub-pixel region 101, the second sub-pixel region 102 and the third sub-pixel region 103 are irradiated by the light of the same wavelength, the leakage currents are identical. Consequently, each of the TFT devices has identical device characteristic, and color deviation is avoided.

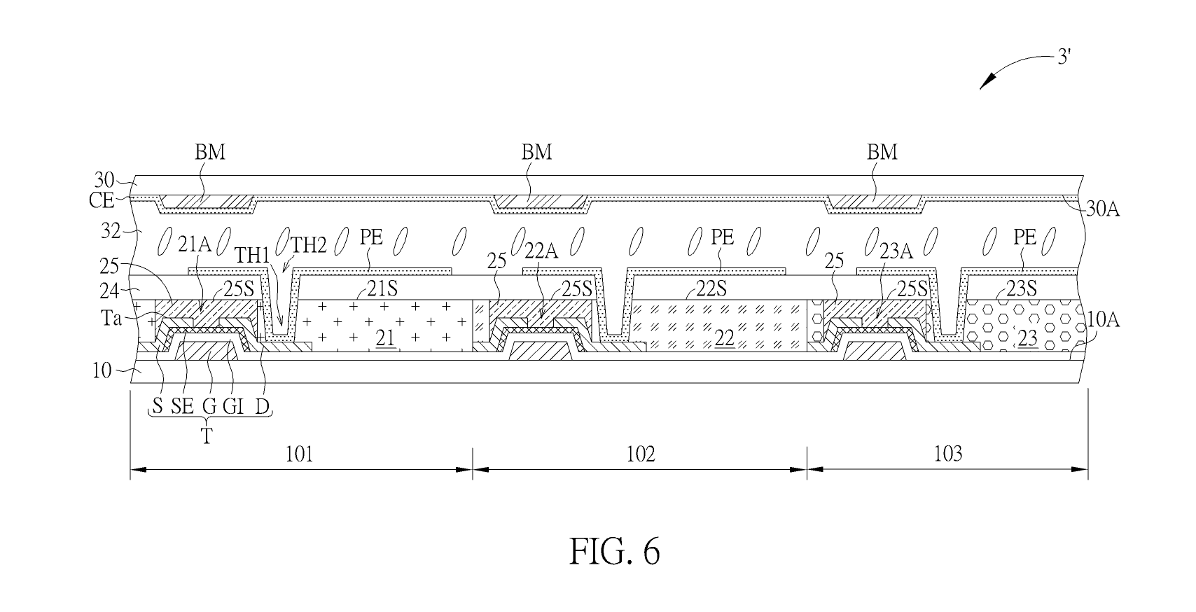

Refer to FIG. 6. FIG. 6 is a schematic diagram illustrating a display panel according to an alternative embodiment of the second embodiment of the present disclosure. As shown in FIG. 6, in the display panel 3′ of the alternative embodiment, the light transmission spectrum of the auxiliary color filter patterns 25 is different from the light transmission spectrum of the first color filter 21, the light transmission spectrum of the second color filter 22 and the light transmission spectrum of the third color filter 23. For example, the light transmission wavelength of the auxiliary color filter patterns 25 is preferably longer than the light transmission wavelength of the first color filter 21, the light transmission wavelength of the second color filter 22 and the light transmission spectrum of the third color filter 23. Accordingly, the leakage currents and device characteristic of the TFT devices T are identical, and color deviation is avoided.

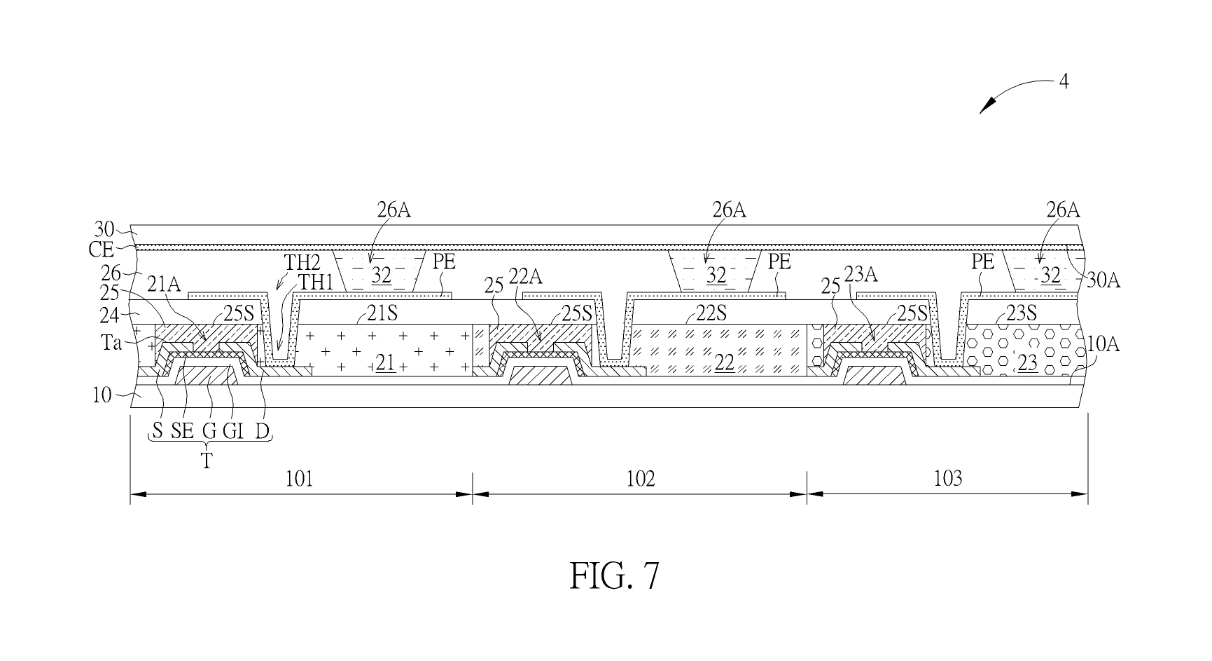

Refer to FIG. 7. FIG. 7 is a schematic diagram illustrating a display panel according to a third embodiment of the present disclosure. As shown in FIG. 7, different from the first embodiment and the second embodiment, the display panel 4 of this embodiment is an electroluminescent display panel e.g. an OLED display panel, wherein the opto-electric medium layer 32 is an electroluminescent layer e.g. an organic light-emitting layer, and the electroluminescent layer may be capable of emitting a white light. In addition, a pixel defining layer (also referred to as a patterned back layer) 26 is disposed on the overcoat layer 24, and the pixel defining layer 26 has a plurality of openings 26A uncovering the pixel electrodes PE respectively. The opto-electric medium layer 32 is disposed in the openings 26A and located on the pixel electrodes PE. In this embodiment, the pixel electrode PE may be a transparent electrode which serves as an anode, and the common electrode CE may be a reflective electrode which serves as a cathode. The pixel electrode PE and the common electrode CE are able to drive the opto-electric medium layer 32 to emit light, which will pass through the first color filter 21, the second color filter 22 and the third color filter 23 and move toward the first substrate 10 to display images. Since the TFT device T of each sub-pixel region is covered with the auxiliary color filter pattern 25 of the same color (the same light transmission spectrum), and thus all the TFT devices T have identical leakage currents and identical device characteristic. Accordingly, color deviation is avoided.

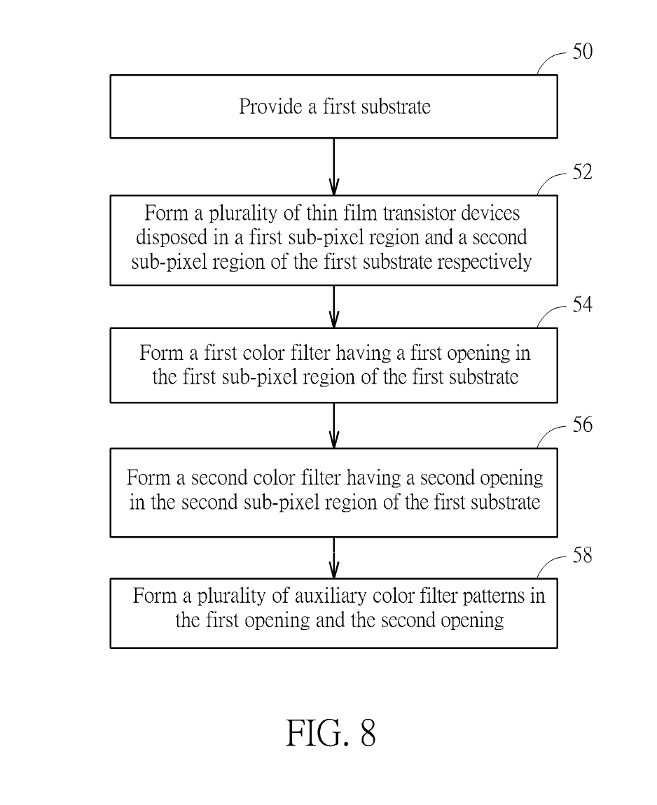

Refer to FIG. 8 as well as FIGS. 3-7. FIG. 8 is a flow chart illustrating a method of fabricating a display panel according an embodiment of the present disclosure. As shown in FIG. 8, the method of fabricating a display panel includes the following steps.

Step 50: As shown in FIGS. 3-7, a first substrate 10 is first provided.

Step 52: As shown in FIGS. 3-7, a plurality of thin film transistor devices T are formed on the first substrate 10 and respectively disposed in a first sub-pixel region 101 and a second sub-pixel region 102 of the first substrate 10.

Step 54: As shown in FIGS. 3-7, a first color filter 21 having a first opening 21A id formed in the first sub-pixel region 101 of the first substrate 10.

Step 56: As shown in FIGS. 3-7, a second color filter 22 having a second opening 22A is formed in the second sub-pixel region 102 of the first substrate 10, wherein the first color filter 21 and the second color filter 22 have different light transmission spectra.

Step 58: As shown in FIGS. 3-7, a plurality of auxiliary color filter patterns 25 are formed in the first opening 21A and the second opening 22A, wherein the auxiliary color filter patterns 25 disposed in the first opening 21A and the second opening 22A have the same light transmission spectrum.

In conclusion, the color filters are disposed on the array substrate, not on the counter substrate, and thus the aperture ratio of the display panel is improved. In addition, the TFT devices of the sub-pixel regions configured to display images of different colors are covered with the auxiliary color filter patterns of the same color, and thus all the TFT devices have identical leakage currents and identical device characteristic. Accordingly, color deviation is avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A display panel comprising:
a first substrate having a first sub-pixel region and a second sub-pixel region;
a plurality of thin film transistor (TFT) devices disposed on a surface of the first substrate and located respectively in the first sub-pixel region and the second sub-pixel region;
a first color filter disposed on the surface of the first substrate of the first sub-pixel region, wherein the first color filter has a first opening at least partially corresponding to the thin film transistor device in the first sub-pixel region;
a second color filter disposed on the surface of the first substrate of the second sub-pixel region, wherein the second color filter has a second opening at least partially corresponding to the thin film transistor device in the second sub-pixel region, and the first color filter and the second color filter have different light transmission spectra; and
a plurality of auxiliary color filter patterns respectively disposed in the first openings and the second openings, wherein the auxiliary color filter patterns disposed in the first openings and the second openings have the same light transmission spectrum.

2. The display panel according to claim 1, wherein the plurality of auxiliary color filter patterns are filled into the first openings and the second openings.

3. The display panel according to claim 1, wherein top surfaces of the auxiliary color filter patterns disposed in the first openings and the second openings, a first top surface of the first color filter and a second top surface of the second color filter are substantially coplanar.

4. The display panel according to claim 1, wherein the auxiliary color filter patterns are in contact with the thin film transistor devices respectively.

5. The display panel according to claim 1, wherein each of the thin film transistor devices comprises a gate electrode, a semiconductor channel layer, a source electrode and a drain electrode, and each of the auxiliary color filter patterns at least fully covers the semiconductor channel layer of the corresponding thin film transistor device.

6. The display panel according to claim 5, wherein each of the first color filter and the second color filter has a first contact hole at least partially uncovering the drain electrode respectively.

7. The display panel according to claim 6, further comprising an overcoat layer disposed on the surface of the first substrate, wherein the overcoat layer covers the first color filter, the second color filter and the auxiliary color filter patterns, and the overcoat layer has a plurality of second contact holes respectively connecting the first contact holes.

8. The display panel according to claim 7, further comprising a plurality of pixel electrodes disposed on the overcoat layer and disposed in the first sub-pixel region and the second sub-pixel region, wherein each of the pixel electrodes is electrically connected to the corresponding drain electrode through the first contact hole and the second contact hole.

9. The display panel according to claim 1, wherein the auxiliary color filter patterns has the same light transmission spectrum as the first color filter or the second color filter.

10. The display panel according to claim 1, wherein the light transmission spectrum of the auxiliary color filter patterns is different from the light transmission spectrum of the first color filter and the light transmission spectrum of the second color filter, and a light transmission wavelength of the auxiliary color filter patterns is longer than a light transmission wavelength of the first color filter and a light transmission wavelength of the second color filter.

11. The display panel according to claim 1, wherein the first color filter and the second color filter are selected from the group consisting of a red color filter, a green color filter, a blue color filter, a yellow color filter, a cyan color filter and a magenta color filter.

12. The display panel according to claim 1, wherein the auxiliary color filter pattern is selected from the group consisting of a red color filter, a green color filter, a blue color filter, a yellow color filter, a cyan color filter and a magenta color filter.

13. The display panel according to claim 12, wherein the auxiliary color filter pattern is the red filter.

14. The display panel according to claim 1, further comprising:
a second substrate disposed opposite to the first substrate;
a black matrix disposed on a surface of the second substrate;
a common electrode disposed on the surface of the second substrate and the black matrix; and
an opto-electrical medium layer interposed between the surface of the first substrate and the surface of the second substrate.

15. The display panel according to claim 14, wherein the opto-electrical medium layer comprises a liquid crystal layer.

16. The display panel according to claim 14, wherein the opto-electrical medium layer comprises an electroluminescent layer.

17. A method of fabricating display panel, comprising:
providing a first substrate;
forming a plurality of thin film transistor (TFT) devices on the first substrate, wherein the thin film transistor devices are respectively disposed in a first sub-pixel region and a second sub-pixel region of the first substrate;
forming a first color filter in the first sub-pixel region of the first substrate, wherein the first color filter has a first opening at least partially corresponding to the thin film transistor device in the first sub-pixel region;
forming a second color filter in the second sub-pixel region of the first substrate, wherein the second color filter has a second opening at least partially corresponding to the thin film transistor device in the second sub-pixel region, and the first color filter and the second color filter have different light transmission spectra; and
forming a plurality of auxiliary color filter patterns in the first openings and the second openings, wherein the auxiliary color filter patterns disposed in the first openings and the second openings have the same light transmission spectrum.

18. The method of fabricating display panel according to claim 17, wherein the first color filter, the second color filter and the auxiliary color filter patterns are formed by exposure-and-development process.

19. The method of fabricating display panel according to claim 18, wherein the first color filter and the auxiliary color filter patterns disposed in the first openings are formed by a same exposure-and-development process, and a light transmission wavelength of the auxiliary color filter patterns and a light transmission wavelength of the first color filter layer are larger than a light transmission wavelength of the second color filter.

20. The method of fabricating display panel according to claim 17, wherein the auxiliary color filter patterns are formed by inkjet printing.
